(19) United States
(12) Patent Application Publication
(10) Pub. No.: US 2008/0086860 A1
(43) Pub. Date: Apr. 17, 2008

(54) METHOD FOR PRODUCING ELECTRONIC COMPONENT

(75) Inventors: Hidetoshi FUJII, Ishikawa-gun (JP); Takahiro OGUCHI, Yasu-shi (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(73) Assignee: MURATA MANUFACTURING CO., LTD., Nagaokakyo-shi (JP)

(21) Appl. No.: 11/935,658

(22) Filed: Nov. 6, 2007

Related U.S. Application Data
(63) Continuation of application No. PCT/JP2006/309719, filed on May 16, 2006.

(30) Foreign Application Priority Data
Jun. 17, 2005 (JP) 2005-177537

(51) Int. Cl. H01L 41/22

(52) U.S. Cl. 29/25.35

(57) ABSTRACT

A method for producing an electronic component prevents problems due to outgassing from a sacrificial layer and the formation of residues during removal of the sacrificial layer. The method includes a first step of forming a sacrificial layer on a substrate, the sacrificial layer being mainly composed of polyamide imide, a second step of forming an elemental portion on part of the sacrificial layer, and a third step of removing the sacrificial layer to form a gap between the elemental portion and the substrate.

### BACKGROUND OF THE INVENTION

1. Field of the Invention

The present invention relates to a method for producing an electronic component. In particular, the present invention relates to a method for producing an electronic component including a sacrificial layer.

2. Description of the Related Art

For electronic components and the like using bulk acoustic wave resonators (BAWs) and micromachine technology (MEMS), a method including forming a membranous elemental portion on part of a sacrificial layer on a substrate and then removing the sacrificial layer has been employed.

For example, Japanese Patent Publication No. 2002-509644 discloses that, in the case where a BAW resonator including an air gap 62, a first protective layer 48, a bottom electrode layer 50, a piezoelectric layer 52, and a top electrode layer 54 formed on a substrate 42 as shown in FIG. 6, a sacrificial layer composed of zinc oxide or a polymer is used to form the air gap 62.

Advantages of the use of a polymer material for the sacrificial layer compared with the use of zinc oxide are as follows: a processing time can be reduced; the smooth surface and end surfaces of the sacrificial layer can be provided; and an etching solution has no adverse effect on the piezoelectric layer and the electrodes, and the like.

However, in the case where the polymer material such as polyimide or polyamide described in Japanese Patent Publication No. 2002-509644 is practically used for the sacrificial layer, problems such as the contamination of a vacuum chamber by outgassing and difficulty in subsequently removing the sacrificial layer because the degree of polymerization of the polymer is increased to stick the polymer on the substrate occurred.

### SUMMARY OF THE INVENTION

In order to overcome the problems described above, preferred embodiments of the present invention provide a method for producing an electronic component that prevents problems due to outgassing from the sacrificial layer and the formation of residues during removal of the sacrificial layer.

To solve the above-described problems, a preferred embodiment of the present invention provides a method for producing an electronic component including the following steps.

A method for producing an electronic component preferably includes a first step to a third step. In the first step, a sacrificial layer mainly composed of polyamide imide is formed on a substrate. In the second step, an elemental portion is formed on a portion of the sacrificial layer. In the third step, the sacrificial layer is removed to form a gap between the elemental portion and the substrate.

The use of the sacrificial layer mainly composed of polyamide imide eliminates outgassing from the sacrificial layer in the second step and facilitates removal of the sacrificial layer in the third step. The use of the sacrificial layer mainly composed of polyamide imide results in the following advantages: for example, a processing time can be reduced; the smooth surface and end surfaces of the sacrificial layer can be provided; and an etching solution has no adverse effect on the piezoelectric layer and the electrodes, compared with that in the case of the use of the sacrificial layer composed of zinc oxide.

Preferably, the elemental portion formed in the second step is an elemental portion of a piezoelectric resonator including a lower electrode, a piezoelectric film, and an upper electrode.

In this case, the smooth surface of the sacrificial layer composed of polyamide imide is transferred, thereby forming the satisfactory elemental portion of the piezoelectric resonator.

Preferably, the method further includes a step of baking the sacrificial layer at a temperature in the range of a temperature at which the piezoelectric film is formed in the second step up to about 280° C., performed between the first step and the second step.

In this case, outgassing from the sacrificial layer is completed before the second step. This eliminates the contamination of the apparatus due to outgassing from the sacrificial layer in steps subsequent to the second step, thereby eliminating failure characteristics due to the inclusion of the released gas in the film.

Preferably, in the second step, the piezoelectric film is formed while the substrate is heated at a temperature in the range of about 150° C. to about 280° C.

In this case, heating the substrate during the formation of the piezoelectric film results in the formation of the satisfactory piezoelectric film, thereby producing a piezoelectric resonator having satisfactory characteristics.

Preferably, the first step includes first to sixth substeps. In the first substep, a polyamide imide film is formed on a surface of the substrate. In the second substep, a photoresist is applied onto the polyamide imide film. In the third substep, the photoresist is irradiated with ultraviolet rays with a photomask for forming the sacrificial layer. In the fourth substep, the photoresist is developed to form a photoresist pattern. In the fifth substep, a portion of the polyamide imide film exposed around the photoresist pattern is removed by dry etching to form the sacrificial layer. In the sixth substep, the photoresist pattern left on the sacrificial layer is removed. The photoresist pattern formed through the second, third, and fourth substeps has an upwardly tapered shape in such a manner that an end surface of the sacrificial layer formed in the fifth substep has an upwardly tapered shape with a taper angle of less than about 85° with respect to the planar direction of the substrate.

In this case, the upwardly tapered shape of the sacrificial layer improves the strength of the membrane of the elemental portion, thereby preventing the destruction of the element.

Preferably, in the third step, the sacrificial layer is removed with at least one organic solvent selected from N-methyl-2-pyrrolidone, hydroxylamine, dimethylacetamide, and dimethylformamide.

In this case, the sacrificial layer can be removed in a short time.

Preferably, the polyamide imide used in the first step is a photosensitive polyamide imide.

In this case, the material film to be formed into the sacrificial layer formed on the substrate can be directly patterned by exposure and development. Thus, the steps of applying the photoresist onto the material film to be formed into the sacrificial layer, exposing and developing the photoresist, patterning (etching) the sacrificial layer, and removing the photoresist are eliminated, thus simplifying the process.

Preferably, in the first step, the sacrificial layer formed in the first step preferably has a surface roughness Ra of about 2 nm or less.

In this case, a surface roughness Ra of about 2 nm or less improves the characteristics of the resonator formed on the sacrificial layer.

The methods for producing an electronic component according to various preferred embodiments of the present invention prevent problems due to outgassing from the sacrificial layer and the formation of the residue during removal of the sacrificial layer.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a fragmentary cross-sectional view of an electronic component according to a first preferred embodiment of the present invention.

FIG. 2 is a fragmentary plan view of the electronic component according to a first preferred embodiment of the present invention.

FIG. 3 is a fragmentary cross-sectional view of an electronic component according to a second preferred embodiment of the present invention.

FIG. 4 is a fragmentary cross-sectional view of an electronic component according to a third preferred embodiment of the present invention.

FIGS. 5A-5E is an explanatory drawing of the production process of the electronic component according to a first preferred embodiment of the present invention.

FIG. 6 is a fragmentary cross-sectional view of a conventional electronic component.

### DETAILED DESCRIPTION OF PREFERRED EMBODIMENTS

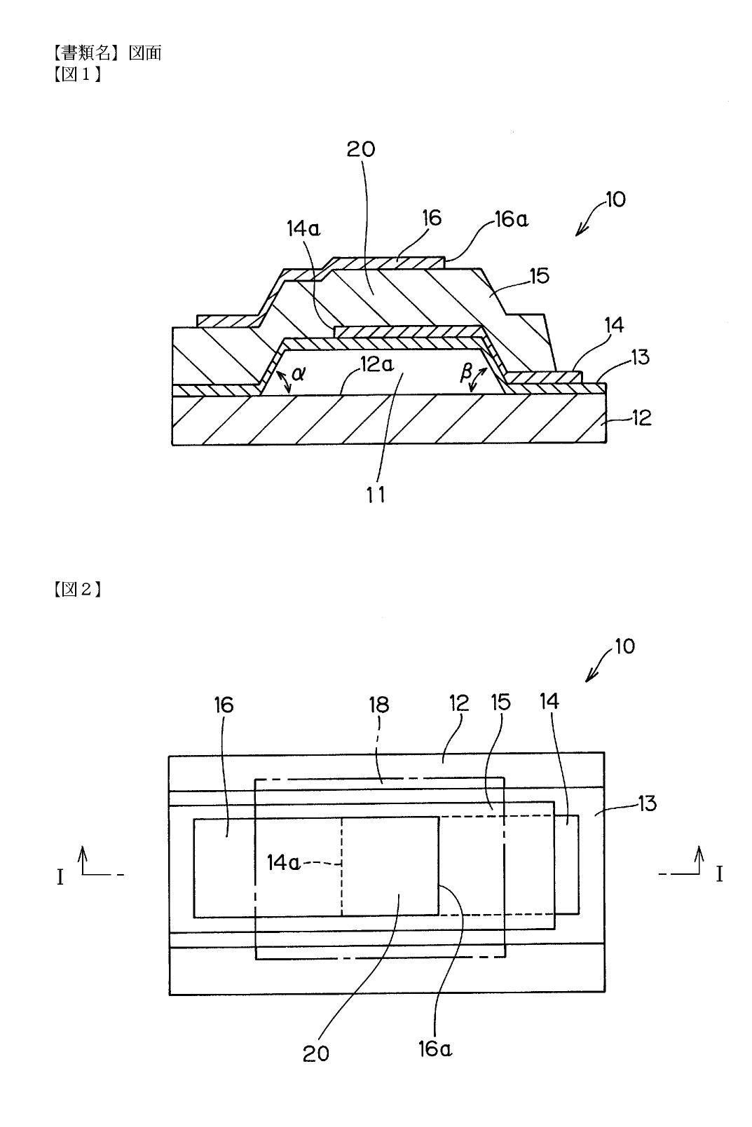

Preferred embodiments of the present invention will be described below with reference to FIGS. 1 to 5.

A piezoelectric thin-film resonator 10 according to a first preferred embodiment will be described with reference to FIGS. 1, 2, and 5. FIGS. 1 and 2 are a fragmentary schematic cross-sectional view and a fragmentary schematic plan view, respectively, of the structure of the piezoelectric thin-film resonator 10. FIG. 1 is a cross-sectional view taken along line I-I in FIG. 2.

The piezoelectric thin-film resonator 10 is a BAW resonator and includes a dielectric film 13, a lower electrode film 14, a piezoelectric film 15, and an upper electrode film 16 disposed on a substrate 12. The piezoelectric thin-film resonator has a membrane structure having a vibrating portion 20 in which the dielectric film 13, the lower electrode film 14, the piezoelectric film 15, and the upper electrode film 16 overlap in the stacking direction of the electrode films 14 and 16 (the vertical direction in FIG. 1 and the direction that is substantially perpendicular to the paper plane in FIG. 2), the vibrating portion 20 floating against the substrate 12 with a gap 11 (see FIG. 1) formed between the substrate 12 and the dielectric film 13 by removing a sacrificial layer 18 (see FIG. 2).

Ends of the membrane structure each have an upwardly tapered shape. That is, at ends of the gap 11, taper angles α and β each defined by the top surface 12a of the substrate 12 and the undersurface of the dielectric film 13 preferably are each less than about 85° and preferably about 45° or less.

The piezoelectric thin-film resonator 10 is produced in a collective substrate (wafer) form through the following steps.

(1) Step of Forming Sacrificial Layer

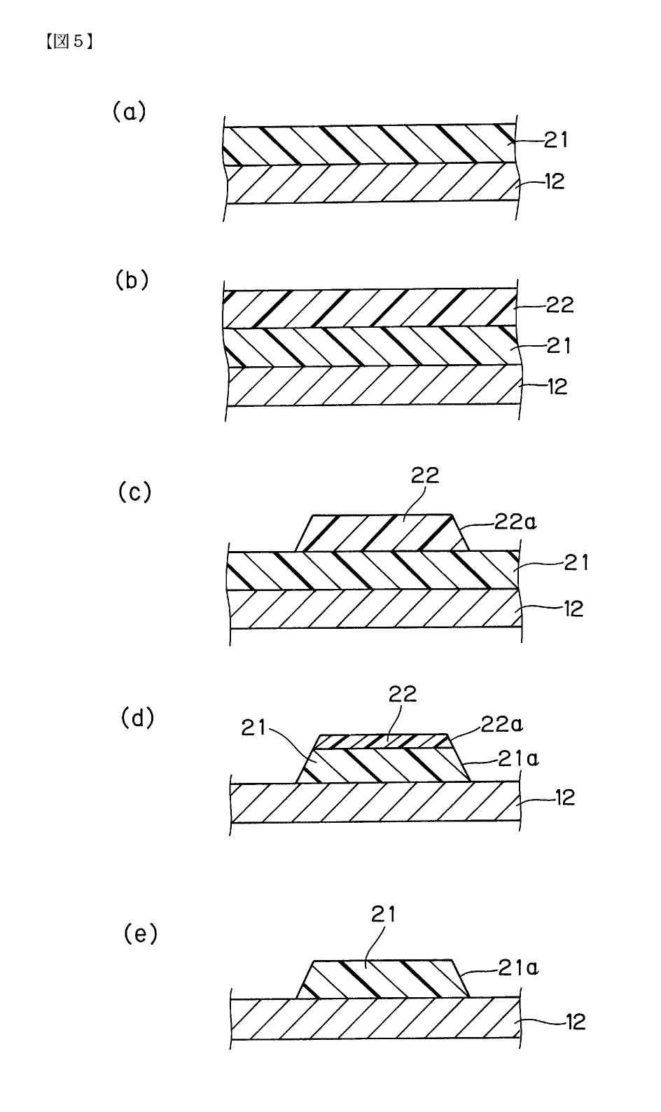

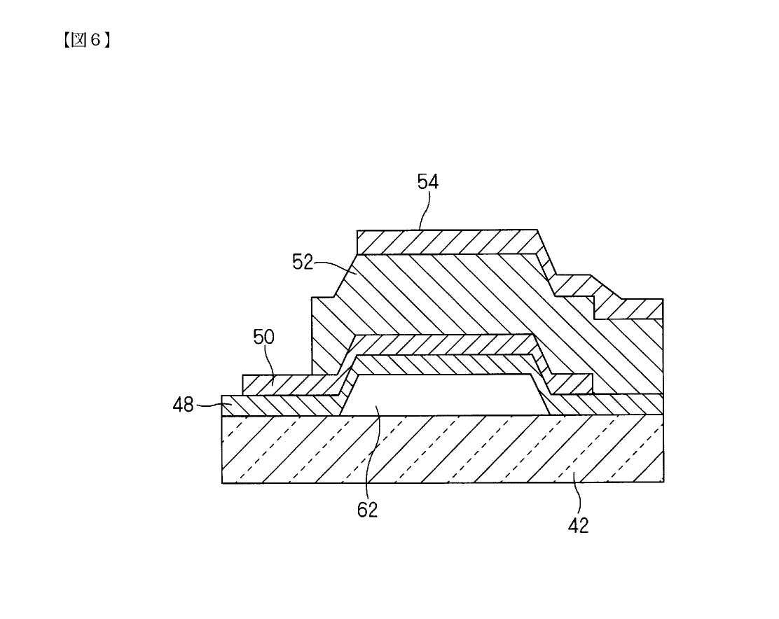

An inexpensive substrate having excellent workability is used as the substrate 12. A Si or glass substrate having a flat surface is preferred. As shown in FIG. 5A, a resin film 21 mainly composed of polyamide imide (hereinafter, referred to as a “polyamide imide film 21”) is formed by spin coating on the substrate 12. Preferably, before spin coating, the polyamide imide resin is diluted in a solvent such as N-methyl-2-pyrrolidone (hereinafter, referred to as “NMP”) so as to have a solid content of several percent to several tens of percent.

The polyamide imide film 21 formed on the substrate 12 is processed to have a shape corresponding to the membrane of the piezoelectric resonator (the shape of the sacrificial layer 18). The sacrificial layer 18 needs to have a thickness such that the vibrating portion 20 does not come into contact with the substrate 12 when the membrane is deformed and thus preferably has a thickness in the range of about 50 nm to several micrometers in view of the ease of production. The minimal distance between the end of the sacrificial layer 18 and the vibrating portion 20 is preferably set to a distance equal to or less than 50 times the thickness of the vibrating portion 20. In this case, also the tapered shape of the sacrificial layer 18 is simultaneously formed.

Specifically, as shown in FIG. 5B, a photoresist 22 is applied onto the polyamide imide film 21. The photoresist 22 is pattered by photolithography. The patterned photoresist 22 is subjected to baking treatment at about 100° C. to about 150° C. for several tens of seconds to several tens of minutes in such a manner that end surfaces 22a of the resist each has a tapered shape (upwardly tapered shape) having an angle (taper angle) of less than about 85° with respect to the planar direction of the substrate 12 as shown in FIG. 5C.

As shown in FIG. 5D, both of the polyamide imide film 21 and the patterned photoresist 22 are then etched by dry etching. The lower portions of the end surfaces 22a are etched to reduce the size thereof. The portions of the polyamide imide film 21 exposed from the end surfaces 22a of the resist are etched. That is, the shapes of the portions of the size-reduced end surfaces 22a of the resist are transferred to the polyamide imide film 21. Therefore, the polyamide imide film 21 (i.e., sacrificial layer 18) has end surfaces 21a each having an upwardly tapered shape. Preferably, the end surfaces 21a of the polyamide imide film 21 each have a taper angle of about 45° or less. A smaller taper angle (gentle taper) results in an increase in the strength of the membrane.

After patterning the polyamide imide film 21 in this way, only the photoresist 22 on the polyamide imide film 21 is removed with an aqueous tetramethylammonium hydroxide solution (TMAH) as shown in FIG. 5E. The polyamide imide resin withstands this alkaline solution (TMAH). Thus, patterning can be performed in a desired region without roughening the surface of the polyamide imide film 21.

A photosensitive polyamide imide may be used as the material for the sacrificial layer. For example, the incorporation of a photosensitizer in polyamide imide or the modification of a polyamide imide resin with a compound having a photosensitive group imparts photosensitivity. In the case of a photosensitive polyamide imide, a photosensitive polyamide imide film (film to be formed into the sacrificial layer) is only directly subjected to exposure and development steps to form the sacrificial layer. Thus, the photoresist does not need to be used, and the steps of applying, exposing, and developing the photoresist, etching the film to be formed into the sacrificial layer, and removing the photoresist can be eliminated.

(1-a) Step of Baking Sacrificial Layer

Then the solvent such as NMP is vaporized by baking at a high temperature of a temperature at which the piezoelectric film 15 is formed to preferably about 280° C. The baking is performed for the time required for removal of the solvent. The baking eliminates the contamination of the apparatus due to outgassing in the subsequent step and abnormality in the quality of the film due to the inclusion of the released gas during formation, thereby stably producing the resonator.

(2) Step of Forming Dielectric Film

The dielectric film 13 is formed by sputtering, CVD, electron beam evaporation, or the like on the substrate including the sacrificial layer so as to cover the entire surface thereof and is then subjected to planarization.

The dielectric film 13 has the effect of protecting the vibrating portion 20 including the electrode films 14 and 16 and the piezoelectric film 15 and may be composed of a nitride such as silicon nitride or oxide such as silicon oxide having excellent passivation.

The use of the dielectric film 13 composed of a material having a temperature coefficient of frequency (TCF) opposite to that of a material constituting the piezoelectric film 15 reduces a change in the frequency of the resonator or a filter with temperature changes, thereby improving characteristics. For example, in the case of the use of the piezoelectric film 15 composed of zinc oxide or aluminum nitride, the dielectric film 13 composed of silicon nitride having a TCF opposite to that of the piezoelectric film.

Alternatively, the dielectric film 13 may be composed of insulative aluminum nitride having satisfactory thermal conductivity.

(3) Step of Forming Lower Electrode Film

A film is formed by sputtering, plating, CVD, electron beam evaporation, or the like on the planarized dielectric film 13 and patterned by photolithography to form the lower electrode film 14. In this case, the lower electrode film 14 mainly composed of a metal material such as Mo, Pt, Al, Au, Cu, or Ti is formed in the form of a strip so as to extend from the sacrificial layer 18 to the substrate 12. That is, as shown in FIGS. 1 and 2, an end 14a of the lower electrode film 14 is located above the sacrificial layer 18.

(4) Step of Forming Piezoelectric Film

A film is formed by sputtering or the like on the lower electrode film 14 and the dielectric film 13 and patterned by photolithography to form the piezoelectric film 15 composed of zinc oxide, aluminum nitride, or the like. To obtain satisfactory film quality, the substrate may be heated to about 150° C. or higher during the formation of the piezoelectric film 15. In this case, the sacrificial layer 18 composed of polyamide imide resin baked in the step “(1-a) Step of Baking Sacrificial Layer” is used. As a result, the piezoelectric film can be formed without the contamination of the apparatus due to outgassing from the sacrificial layer 18 or abnormality in the quality of the film.

The piezoelectric film 15 is formed into a shape shown in FIG. 2 by etching such as wet etching with a resin, e.g., a photoresist, as a mask. When the piezoelectric film 15 is composed of zinc oxide (ZnO), the zinc oxide thin film can be easily etched with an acidic aqueous solution such as a mixed aqueous solution of phosphoric acid and acetic acid. When the piezoelectric film 15 is composed of aluminum nitride (AlN), the film can be etched with an aqueous tetramethylammonium hydroxide solution (TMAH). The same polyamide imide resin as the material constituting the sacrificial layer may be used as a mask for this etching.

(5) Step of Forming Upper Electrode Film

The upper electrode film 16 is formed on the piezoelectric film 15 in the same way as in the lower electrode film 14. In this case, an end 16a of the upper electrode film 16 is located above the sacrificial layer 18 as shown in FIGS. 1 and 2.

(6) Step of Forming Etch Hole

A portion at which the sacrificial layer 18 is exposed, i.e., an etch hole (not shown), is formed. Patterning a photoresist or the like is performed by photolithography. The dielectric film 13 on the sacrificial layer 18 is removed by reactive ion etching or wet etching to form the etch hole. For example, when the dielectric film 13 is composed of silicon oxide, reactive ion etching is performed with a fluorine-containing gas such as CF4. Alternatively, wet etching may be performed with a solution such as hydrofluoric acid. After etching, the etch mask such as a photoresist is removed with an organic solvent such as acetone. Alternatively, dry etching may be performed with an oxygen plasma.

(7) Step of Forming Gap

The sacrificial layer 18 is etched through the etch hole to form the gap 11. When the sacrificial layer is composed of zinc oxide, the sacrificial layer must be etched with an acidic aqueous solution. Thus, in the case where the electrodes are composed of Al or the like which is etched with an acid, it is necessary to protect the electrodes by patterning a photoresist or the like using photolithography. On the other hand, when the sacrificial layer is composed of polyamide imide, the sacrificial layer can be easily removed with NMP. The polyamide imide is removed with NMP. Washing and drying are performed to remove the sacrificial layer 18, thereby forming the gap 11. After the removal of the sacrificial layer with NMP, dry etching with an oxygen plasma or the like may be combined.

The polyamide imide can be removed with any of hydroxylamine, dimethylacetamide, and dimethylformamide in place of NMP.

The resulting piezoelectric thin-film resonator 10 includes the sacrificial layer composed of baked polyamide imide resin and can thus eliminate outgassing from the sacrificial layer after the step of forming the sacrificial layer. This eliminates problems in the process due to the contamination of the apparatus and the like, thereby stably producing the resonator.

The use of the polyamide imide resin baked eliminates outgassing, thereby improving a deterioration in the characteristics of the resonator caused by an adverse effect such as abnormality in the quality of the film due to the inclusion of the released gas during the formation of the film.

The polyamide imide resin can be easily removed with a solvent such as NMP even when the resin is subjected to heat treatment at about 280° C. Thus, the sacrificial layer can be easily wet-etched with NMP for a short time in the step of forming the gap. Furthermore, NMP does not etch electrodes composed of Al, Cu, or the like or the piezoelectric film composed of ZnO, AlN, or the like. Therefore, the films constituting the resonator are not etched in the step of forming the gap, thereby stably producing the resonator.

Sacrificial layers composed of polyamide imide, polyimide, and polyamide were formed on a Si substrate and were baked at various heating temperatures to form samples. The samples were immersed in a NMP solution to evaluate detachability. The polyamide imide was easily detached even at a heating temperature of 280° C., whereas the detachability of the polyimide and polyamide was degraded at such high-temperature treatment. When a thermal load is applied at about 280° C. or higher for a prolonged period of time, even polyamide imide cannot be easily removed because self cross-linking occurs. Therefore, the heating temperature during baking and temperatures in the subsequent steps (for example, the step of forming the piezoelectric film 15) are preferably about 280° C. or less.

To obtain satisfactory resonance characteristic, the surfaces of the films constituting the resonator must be flat. When the sacrificial layer is composed of ZnO, the layer is usually formed by sputtering. In this case, the surface roughness Ra of ZnO is about 2 nm to several nanometers. In contrast, the surface roughness Ra of the polyamide imide resin is about 0.2 to about 0.5 nm, which is extremely flat. When the sacrificial layer composed of the polyamide imide resin has a surface roughness Ra of about 2 nm or less, the characteristics of the resonator can be improved.

The presence of irregularities, e.g., particles, of the surface of the sacrificial layer results in the formation of cracks in the electrodes and the piezoelectric film, causing element failure, such as failure in power durability or insulation resistance. In the case where ZnO is formed by sputtering, many particles are formed, thus easily causing element failure. In contrast, the polyamide imide resin has an extremely smooth surface without particles, thereby reducing element failure.

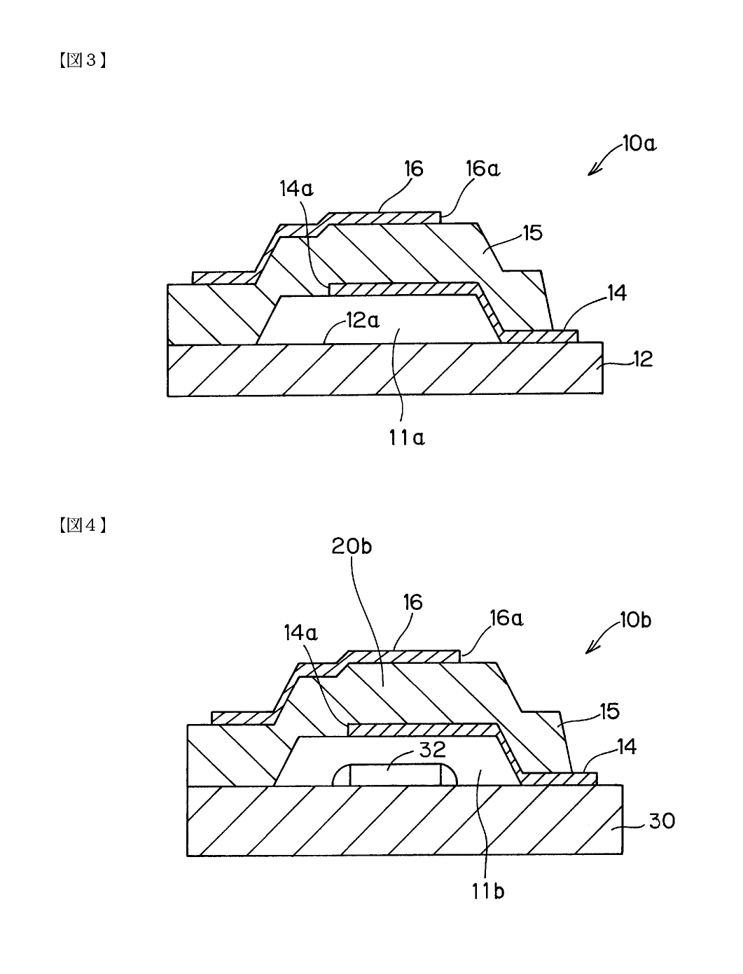

A piezoelectric thin-film resonator 10a according to a second preferred embodiment will be described with reference to FIG. 3.

The piezoelectric thin-film resonator 10a preferably has substantially the same structure as that of the piezoelectric thin-film resonator 10 in the first preferred embodiment and preferably is formed in substantially the same way. Hereinafter, the same elements as those in the first preferred embodiment are designated using the same reference numerals. The differences from the first preferred embodiment will be mainly described.

Unlike the piezoelectric thin-film resonator 10 in the first preferred embodiment, the piezoelectric thin-film resonator 10a does not include a dielectric film between the substrate 12 and the lower electrode film 14.

One difference in the method of the second preferred embodiment is that it eliminates the step “(2) Step of Forming Dielectric Film” described in the first preferred embodiment in the production of the piezoelectric thin-film resonator 10a. Furthermore, the step “(6) Step of Forming Etch Hole” may be omitted, thereby increasing reliability in the process and reducing the number of steps to reduce costs. The other steps are substantially the same as in those in the first preferred embodiment.

However, in the steps “(3) Step of Forming Lower Electrode Film”, “(4) Step of Forming Piezoelectric Film”, and “(5) Step of Forming Upper Electrode Film”, the sacrificial layer is not protected because of the absence of the dielectric film. Thus, an organic solvent capable of dissolving the polyamide imide resin constituting the sacrificial layer is not used. A non-NMP-based organic solvent, such as acetone, that does not dissolve the polyamide imide resin is used for lift-off in the step “(3) Step of Forming Lower Electrode Film” and “(5) Step of Forming Upper Electrode Film” and the removal of the mask in the step “(4) Step of Forming Piezoelectric Film.”

A piezoelectric thin-film resonator 10b according to a third preferred embodiment will be described with reference to FIG. 4.

In the piezoelectric thin-film resonator 10b, the elemental portion of the BAW resonator is formed on another functional device 30. Thus, the piezoelectric thin-film resonator 10b has the function of the functional device 30. For example, the another functional device 30 is an LC circuit formed on a Si substrate, a high-frequency device on a GaAs substrate, a ceramic multilayer substrate such as a low-temperature co-fired ceramic (LTCC) substrate, or a balun.

In the same way as in the second preferred embodiment, the piezoelectric thin-film resonator 10b is formed with the sacrificial layer composed of polyamide imide and includes the lower electrode film 14, the piezoelectric film 15, and the upper electrode film 16 on the functional device 30, a vibrating portion 20b being separated from the functional device 30 with a gap 11b.

The smooth sacrificial layer can be formed by spin coating or the like and can be easily formed on an uneven surface. Thus, even when the functional device 30 has irregularities, the elemental portion of the BAW resonator can be formed thereon. Thereby, the piezoelectric thin-film resonator 10b can incorporate a peripheral circuit and the like in addition to the BAW resonator or a filter, thus achieving higher functionality and reducing the size and height.

Alternatively, flat polyamide imide is formed by spin coating on the functional device 30 having irregularities because a surface-mount component 32 such as an IC or a chip component is mounted thereon. After the elemental portion is formed on the sacrificial layer in which the surface-mount component 32 is embedded, the sacrificial layer is removed to arrange the surface-mount component 32 in the gap 11b.

The use of the organic material mainly composed of the polyamide imide resin as the polymer material used for forming the sacrificial layer results in the following advantages.

(1) The sacrificial layer having a thickness of about 0.3 to several micrometers can be formed by spin coating.

(2) Since baking is performed at about 280° C. after the formation of the sacrificial layer and before the formation of the elemental portion, the piezoelectric film having satisfactory quality can be formed without the contamination of the apparatus due to outgassing during heat treatment in the formation of the piezoelectric film.

(3) The sacrificial layer can be easily removed with an organic solvent such as NMP, hydroxylamine, dimethylacetamide, or dimethylformamide even after baking the sacrificial layer.

(4) The surface roughness Ra of the sacrificial layer is about 0.4 nm, which is extremely flat.

(5) The sacrificial layer has excellent chemical resistance and thus is not etched in other steps, thereby forming a desired structure.

The method for producing an electronic component of the present invention is not limited to the above-described preferred embodiments. Various modifications may be made.

The present invention can be applied to the production of various electronic components, such as sensors and switches, using micromachine technology (MEMS) as well as BAW resonators. In particular, the present invention is suitable for electronic components including piezoelectric films.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A method for producing an electronic component, comprising:
a first step of forming a sacrificial layer on a substrate, the sacrificial layer being mainly composed of polyamide imide;
a second step of forming an elemental portion on a portion of the sacrificial layer; and
a third step of removing the sacrificial layer to form a gap between the elemental portion and the substrate.

2. The method for producing an electronic component according to claim 1, wherein the elemental portion formed in the second step is an elemental portion of a piezoelectric resonator including a lower electrode, a piezoelectric film, and an upper electrode.

3. The method for producing an electronic component according to claim 2, the method further comprising a step of baking the sacrificial layer at a temperature in the range of a temperature at which the piezoelectric film is formed in the second step up to about 280° C., performed between the first step and the second step.

4. The method for producing an electronic component according to claim 2, wherein in the second step, the piezoelectric film is formed while the substrate is heated at a temperature in the range of about 150° C. to about 280° C.

5. The method for producing an electronic component according to claim 1, wherein the first step includes:
a first substep of forming a polyamide imide film on a surface of the substrate;
a second substep of applying a photoresist onto the polyamide imide film;
a third substep of irradiating the photoresist with ultraviolet rays with a photomask for forming the sacrificial layer;
a fourth substep of developing the photoresist to form a photoresist pattern;
a fifth substep of removing a portion of the polyamide imide film exposed around the photoresist pattern by dry etching to form the sacrificial layer; and
a sixth substep of removing the photoresist pattern left on the sacrificial layer; wherein
the photoresist pattern formed through the second, third, and fourth substeps has an upwardly tapered shape such that an end surface of the sacrificial layer formed in the fifth substep has an upwardly tapered shape with a taper angle of less than about 85° with respect to the planar direction of the substrate.

6. The method for producing an electronic component according to claim 1, wherein in the third step, the sacrificial layer is removed with at least one organic solvent selected from N-methyl-2-pyrrolidone, hydroxylamine, dimethylacetamide, and dimethylformamide.

7. The method for producing an electronic component according to claim 1, wherein the polyamide imide used in the first step is a photosensitive polyamide imide.

8. The method for producing an electronic component according to claim 2, wherein the sacrificial layer formed in the first step has a surface roughness Ra of about 2 nm or less.
